(19) United States
(12) Patent Application Publication
(10) Pub. No.: US 2013/0334496 A1
(43) Pub. Date: Dec. 19, 2013

(54) SEMICONDUCTOR DEVICE, SUPERLATTICE LAYER USED IN THE SAME, AND METHOD FOR MANUFACTURING SEMICONDUCTOR DEVICE

(71) Applicants: Jae-kyun KIM, Hwaseong-si (KR); Jun-youn KIM, Hwaseong-si (KR); Young-jo TAK, Hwaseong-si (KR)

(72) Inventors: Jae-kyun KIM, Hwaseong-si (KR); Jun-youn KIM, Hwaseong-si (KR); Young-jo TAK, Hwaseong-si (KR)

(21) Appl. No.: 13/838,963

(22) Filed: Mar. 15, 2013

(30) Foreign Application Priority Data
Jun. 13, 2012 (KR) 10-2012-0063404

(51) Int. Cl. H01L 29/205; H01L 21/02

(52) U.S. Cl. CPC H01L 29/205; H01L 21/02507
USPC 257/18; 438/478

(57) ABSTRACT

A semiconductor device includes a silicon substrate; a nitride nucleation layer disposed on the silicon substrate; at least one superlattice layer disposed on the nitride nucleation layer; and at least one gallium nitride-based semiconductor layer disposed on the superlattice layer. The at least one superlattice layer includes a stack of complex layers, each complex layer including a first layer and a second layer such that each of the complex layers has a plurality of nitride semiconductor layers having different compositions, at least one of the plurality of nitride semiconductor layers having a different thickness based on a location of the at least one nitride semiconductor layer within the stack, and at least one stress control layer having a thickness greater than a critical thickness for pseudomorphic growth.

### CROSS-REFERENCE TO RELATED APPLICATIONS

This application claims the benefit of Korean Patent Application No. 10-2012-0063404, filed on Jun. 13, 2012, in the Korean Intellectual Property Office, the disclosure of which is incorporated herein in its entirety by reference.

### BACKGROUND

1. Field

At least one example embodiment relates to semiconductor devices, superlattice layers used in the same, and methods for manufacturing semiconductor devices, and more particularly, to a semiconductor device of which generation of cracks is reduced by reducing tensile stress, a superlattice layer used in the same, and a method for manufacturing a semiconductor device.

2. Description of the Related Art

Sapphire is widely used as a substrate for forming a nitride-based semiconductor device. However, a sapphire substrate is expensive, difficult to manufacture for semiconductor chips, and has low electrical conductivity. Also, when a sapphire substrate is epitaxially grown to have a large diameter, the sapphire substrate may bend at a high temperature due to low thermal conductivity, and thus, it is difficult to manufacture a sapphire substrate having a large area. Accordingly, a gallium nitride-based semiconductor device using a silicon substrate instead of a sapphire substrate is being developed.

Since a silicon substrate has higher thermal conductivity than a sapphire substrate, the silicon substrate does not bend as much even at the high temperature for growing a gallium nitride-based semiconductor thin film, and thus, a thin film having a large diameter may be grown. However, when the gallium nitride-based semiconductor thin film is grown on the silicon substrate, dislocation density is increased due to different lattice constants between the silicon substrate and the gallium nitride-based semiconductor thin film. As a result, cracking occurs as tensile stress is generated in the gallium nitride-based semiconductor thin film due to different thermal expansion coefficients. In order to reduce the generation of cracks, a method of compensating for the tensile stress generated due to the different thermal expansion coefficients includes applying compressive stress on the gallium nitride-based semiconductor thin film.

### SUMMARY

Provided are semiconductor devices and/or superlattice layers used in the same, which are capable of providing a more efficient compressive stress so as to compensate for tensile stress generated due to a thermal expansion coefficient difference between a silicon substrate and a gallium nitride-based semiconductor.

Additional aspects will be set forth in part in the description which follows and, in part, will be apparent from the description, or may be learned by practice of the presented example embodiments.

According to at least one example embodiment, a semiconductor device includes a silicon substrate; a nitride nucleation layer disposed on the silicon substrate; at least one superlattice layer disposed on the nitride nucleation layer; and at least one gallium nitride-based semiconductor layer disposed on the superlattice layer. The at least one superlattice layer includes a stack of complex layers, each complex layer including a first layer and a second layer such that each of the complex layers has a plurality of nitride semiconductor layers having different compositions, at least one of the plurality of nitride semiconductor layers having a different thickness based on a location of the at least one nitride semiconductor layer within the stack, and at least one stress control layer having a thickness greater than a critical thickness for pseudomorphic growth, the at least one stress control layer being disposed between one of the plurality of nitride semiconductor layers and the complex layers.

According to at least one example embodiment, the nitride nucleation layer comprises aluminum nitride (AlN).

According to at least one example embodiment, each of the first layers comprises Alₓ₁In_{y1}Ga_{1-x1-y1}N and each of the second layers comprises Alₓ₂In_{y2}Ga_{1-x2-y2}N, and the first and second layers are stacked on each other, wherein 0<x1≦1, 0≦x2<1, x1>x2, 0≦y1<1, and 0≦y2<1.

According to at least one example embodiment, the at least one stress control layer comprises Alₓ₃In_{y3}Ga_{1-x3-y3}N, wherein 0<x3≦1 and 0≦y3<1.

According to at least one example embodiment, the at least one stress control layer has a thickness greater than 3 nm and less than or equal to 20 nm, so as not to exceed a crack strength.

According to at least one example embodiment, at least one of the first layers and second layers within each of the complex layers has a different thickness based on a location of the first layers and second layers within the stack, and the thicknesses of at least one of the first layers and second layers increase or decrease from the nitride nucleation layer toward the at least one gallium nitride-based semiconductor layer.

According to at least one example embodiment, at least one of the first layers and second layers within each complex layer has a different thickness that varies randomly within the stack.

According to at least one example embodiment, the at least one stress control layer is between the first layer and the second layer.

According to at least one example embodiment, the at least one stress control layer is integrally formed with the first layer.

According to at least one example embodiment, each of the first layer and the second layer has a thickness of about several Å to about several nm, and the at least one stress control layer has a thickness of about several nm to about dozens of nm.

According to at least one example embodiment, at least one value of x1, x2, and x3 changes according to at least one of a thickness of the first layer, second layer, and the at least one stress control layer.

According to at least one example embodiment, the at least one superlattice layer is a plurality of superlattice layers and an average aluminum (Al) composition of each of the plurality of superlattice layers decreases from the nitride nucleation layer toward the at least one gallium nitride-based semiconductor layer.

According to at least one example embodiment, a semiconductor device includes a silicon substrate, a nitride nucleation layer disposed on the silicon substrate, a plurality of superlattice layers disposed on the nitride nucleation layer; and at least one gallium nitride-based semiconductor layer formed on the plurality of superlattice layers. Each of the plurality of superlattice layers includes a stack of complex layers, each complex layer including a first layer and a second layer such that each of the complex layers has a plurality of nitride semiconductor layers having different compositions, and at least one of the plurality of nitride semiconductor layers having a different thickness based on a location of the at least one nitride semiconductor layer within the stack, and an average Al composition of each of the plurality of superlattice layers decreases from the nitride nucleation layer toward the at least one gallium nitride-based semiconductor layer.

According to at least one example embodiment, the nitride nucleation layer comprises AlN.

According to at least one example embodiment, the first layer comprises Alₓ₁In_{y1}Ga_{1-x1-y1}N and the second layer comprises Alₓ₂In_{y2}Ga_{1-x2-y2}N, and the first and second layers are stacked on each other, wherein 0<x1≦1, 0≦x2<1, x1>x2, 0≦y1<1, and 0≦y2<1.

According to at least one example embodiment, at least one of the first layers and second layers within each of the complex layers may have a different thickness based on a location of the first layers and second layers within the stack. The thicknesses of at least one of the first layers and second layers may increase or decrease from the nitride nucleation layer toward the at least one gallium nitride-based semiconductor layer.

According to at least one example embodiment, at least one of the first layers and the second layers within each complex layer may have a different thickness that varies randomly within the stack.

According to at least one example embodiment, the first layer and the second layer may have thicknesses of about several Å to about several nm.

According to at least one example embodiment, at least one value of x1 and x2 changes according to at least one of a thickness of the first layer and the second layer.

According to at least one example embodiment, a superlattice layer includes a stack of complex layers, each complex layer including, a plurality of nitride semiconductor layers having different compositions, at least one of the plurality of nitride semiconductor layers having a different thickness based on a location of the at least one nitride semiconductor layer within the stack, and at least one stress control layer having a thickness greater than a critical thickness for pseudomorphic growth and disposed between the plurality of nitride semiconductor layers or between the complex layers in the stack.

According to at least one example embodiment, a method of manufacturing a semiconductor device, the method including: stacking a nitride nucleation layer on a silicon substrate; stacking at least one superlattice layer on the nitride nucleation layer; and stacking at least one gallium nitride-based semiconductor layer on the at least one superlattice layer, the superlattice layer including, a stack of complex layers, each complex layer including a first layer and a second layer such that each of the complex layers has a plurality of nitride semiconductor layers having different compositions, at least one of the plurality of nitride semiconductor layers having a different thickness based on a location of the at least one nitride semiconductor layer within the stack, and at least one stress control layer having a thickness greater than a critical thickness for pseudomorphic growth, the at least one stress control layer being disposed between one of the plurality of nitride semiconductor layers and the complex layers.

According to at least one example embodiment, the at least one stress control layer may have a thickness greater than 3 nm and less than or equal to 20 nm, so as not to exceed a crack strength.

According to at least one example embodiment, the method may further include removing the silicon substrate, the nitride nucleation layer, and the at least one superlattice layer from the gallium nitride-based semiconductor layer.

According to at least one example embodiment, a method of manufacturing a semiconductor device, the method including: stacking a nitride nucleation layer on a silicon substrate; stacking a plurality of superlattice layers on the nitride nucleation layer; and stacking at least one gallium nitride-based semiconductor layer on the plurality of superlattice layers, each of the plurality of superlattice layers including, a stack of complex layers, each complex layer including a first layer and a second layer such that each of the complex layers has a plurality of nitride semiconductor layers having different compositions, and at least one of the plurality of nitride semiconductor layers having a different thickness based on a location of the at least one nitride semiconductor layer within the stack, and an average Al composition of each of the plurality of superlattice layers decreases from the nitride nucleation layer toward the at least one gallium nitride-based semiconductor layer.

According to at least one example embodiment, the method may further include removing the silicon substrate, the nitride nucleation layer, and the plurality of superlattice layers from the gallium nitride-based semiconductor layer.

### BRIEF DESCRIPTION OF THE DRAWINGS

These and/or other aspects will become apparent and more readily appreciated from the following description of the example embodiments, taken in conjunction with the accompanying drawings in which:

FIG. 1 is a view schematically illustrating a semiconductor device according to an example embodiment;

FIGS. 2A and 2B are magnified views of a superlattice layer of FIG. 1, according to at least one example embodiment;

FIG. 3 is a magnified view of the superlattice layer of FIG. 1, according to another example embodiment;

FIGS. 4A and 4B are magnified views of the superlattice layer of FIG. 1, according to at least one other example embodiment;

FIG. 5 is a magnified view of the superlattice layer of FIG. 1, according to at least another example embodiment;

FIGS. 6A and 6B are views for describing composition changes according to thicknesses of the superlattice layer of FIG. 1, according to at least one example embodiment;

FIG. 7 is a view schematically illustrating a plurality of superlattice layers according to at least one example embodiment;

FIGS. 8A through 8C are magnified views respectively illustrating the plurality of superlattice layers of FIG. 7, according to at least one example embodiment;

FIGS. 9A through 9C are magnified views respectively illustrating the plurality of superlattice layers of FIG. 7, according to at least another example embodiment;

FIG. 10 is a view illustrating a semiconductor device applied to a light-emitting device, according to at least another example embodiment; and

FIG. 11 is a view of a semiconductor device manufactured by using a method of manufacturing a semiconductor device, according to at least one example embodiment.

### DETAILED DESCRIPTION OF EXAMPLE EMBODIMENTS

Hereinafter, a semiconductor device will be described more fully with reference to the accompanying drawings. In the drawings, like reference numerals denote like elements, and the sizes and thicknesses of elements may be exaggerated for clarity.

The example embodiments may, however, be embodied in many different forms and should not be construed as being limited to those set forth herein. Rather, these example embodiments are provided so that this disclosure will be thorough and complete. In at least some example embodiments, well-known device structures and well-known technologies will not be specifically described in order to avoid ambiguous interpretation.

It will be understood that when an element is referred to as being “connected to” or “coupled to” another element, it can be directly on, connected or coupled to the other element or intervening elements may be present. In contrast, when an element is referred to as being “directly connected to” or “directly coupled to” another element, there are no intervening elements present. Like numbers refer to like elements throughout. As used herein, the term “and/or” includes any and all combinations of one or more of the associated listed items.

It will be understood that, although the terms first, second, third, etc., may be used herein to describe various elements, components and/or sections, these elements, components and/or sections should not be limited by these terms. These terms are only used to distinguish one element, component or section from another element, component or section. Thus, a first element, component or section discussed below could be termed a second element, component or section without departing from the teachings of the example embodiments.

The terminology used herein is for the purpose of describing particular example embodiments only and is not intended to be limiting. As used herein, the singular forms “a”, “an” and “the” are intended to include the plural forms as well, unless the context clearly indicates otherwise. It will be further understood that the terms “comprises,” “comprising,” “includes,” and/or “including” when used in this specification, specify the presence of stated components, steps, operations, and/or elements, but do not preclude the presence or addition of one or more other components, steps, operations, elements, and/or groups thereof.

Unless otherwise defined, all terms (including technical and scientific terms) used herein have the same meaning as commonly understood by one of ordinary skill in the art to which these example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Spatially relative terms, such as “below”, “beneath”, “lower”, “above”, “upper”, and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

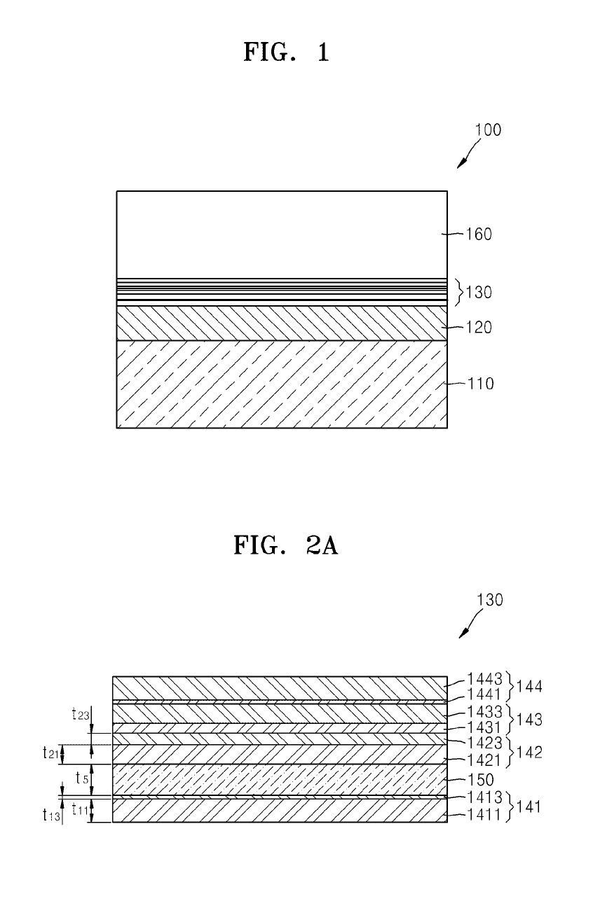

FIG. 1 is a view schematically illustrating a semiconductor device 100 according to an example embodiment. The semiconductor device 100 shown in FIG. 1 may include a silicon substrate 110, a nitride nucleation layer 120 disposed on the silicon substrate 110, a superlattice layer 130 disposed on the nitride nucleation layer 120, and a gallium nitride-based semiconductor layer 160 disposed on the superlattice layer 130.

The silicon substrate 110 is a substrate containing silicon (Si) and may have a large diameter. For example, the silicon substrate 110 may have a diameter greater than or equal to 8 inches. The silicon substrate 110 may be doped with p-type or n-type impurities. The p-type impurities may include at least one selected from the group consisting of boron (B), aluminum (Al), magnesium (Mg), calcium (Ca), zinc (Zn), cadmium (Cd), mercury (Hg), and gallium (Ga), and the n-type impurities may include at least one selected from the group consisting of arsenic (As) and phosphorous (P). When the p-type impurities are doped at high concentration, a bending phenomenon of the silicon substrate 110 may be reduced. The silicon substrate 110 may use a (111) surface. The silicon substrate 110 may be cleaned with peroxosulfuric acid, hydrofluoric acid, or deionized water. Impurities, such as a metal and organic matters, and a natural oxide film may be removed from the silicon substrate 110 that has been cleaned, and a surface of the silicon substrate 110 may be terminated by using hydrogen and may become suitable for epitaxial growth. The silicon substrate 110 may be removed during or after manufacturing of the semiconductor device 100.

The nitride nucleation layer 120 is disposed on the silicon substrate 110 and mitigates (or alternatively, prevents) a melt-back phenomenon caused when the silicon substrate 110 and the superlattice layer 130, or the silicon substrate 110 and the gallium nitride-based semiconductor layer 160 react with each other. Also, the nitride nucleation layer 120 may enable the superlattice layer 130 or the gallium nitride-based semiconductor layer 160 to be well wetted. A material of the nitride nucleation layer 120 may include aluminum nitride (AlN). The nitride nucleation layer 120 may be removed with the silicon substrate 110 during or after manufacturing of the semiconductor device 100.

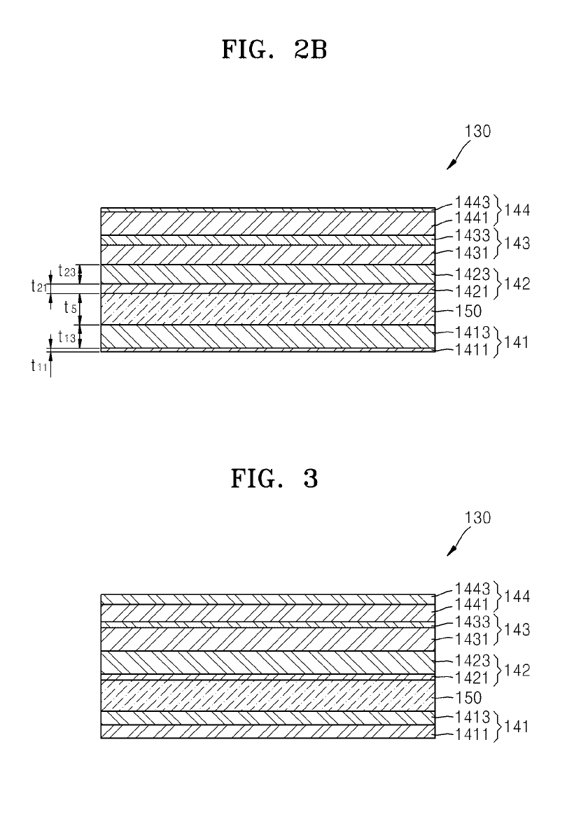

FIG. 2A is a magnified view of the superlattice layer 130 of FIG. 1, according to an example embodiment.

Referring to FIG. 2A, the superlattice layer 130 is formed by repeatedly stacking complex layers 141, 142, 143, and 144, each complex layer including a plurality of nitride semiconductor layers 1411 and 1413, 1421 and 1423, 1431 and 1433, and 1441 and 1443, respectively. The nitride semiconductor layers 1411 through 1443 may have different compositions and different lattice constants. By repeatedly stacking the nitride semiconductor layers 1411 through 1443 having different lattice constants, the superlattice layer 130 may have a new lattice constant different from those of the individual layers in nitride semiconductor layers 1411 through 1443. Accordingly, the nitride semiconductor layers 1411 through 1443 may each have a thickness less than or equal to a critical thickness for pseudomorphic growth. The critical thickness for pseudomorphic growth may refer to a maximum thickness of a thin film growing under an effect of a lattice constant of a substrate material before the thin film takes on an intrinsic lattice constant while being grown on a substrate.

The nitride semiconductor layers 1411 through 1443 forming the complex layers 141 through 144 may be two or more layers. However, for convenience of description, the complex layers 141 through 144 each include two nitride semiconductor layers.

The plurality of nitride semiconductor layers 1411 through 1443 may be first layers 1411, 1421, 1431, and 1441, and second layers 1413, 1423, 1433, and 1443 as shown in FIG. 2A. The first layers 1411, 1421, 1431, and 1441 may include Alₓ₁In_{y1}Ga_{1-x1-y1}N. The second layers 1413, 1423, 1433, and 1443 are respectively stacked on the first layers 1411, 1421, 1431, and 1441 and may include Alₓ₂In_{y2}Ga_{1-x2-y2}N (0<x1≦1, 0≦x2<1, 0≦y1<1, and 0≦y2<1). The first layers 1411, 1421, 1431, and 1441 and the second layers 1413, 1423, 1433, and 1443 may have different compositions, for example, different Al amounts (i.e., x1>x2). For example the first layers 1411, 1421, 1431, and 1441 may be layers including AlN, and the second layers 1413, 1423, 1433, and 1443 may be layers including gallium nitride (GaN). Alternatively, the first layers 1411, 1421, 1431, and 1441 may include AlGaN, and the second layers 1413, 1423, 1433, and 1443 may include GaN. In FIG. 2A, the second layers 1413, 1423, 1433, and 1443 are respectively stacked on the first layers 1411, 1421, 1431, and 1441 as stacked structures of the complex layers 141, 142, 143, and 144, but alternatively, the first layers 1411, 1421, 1431, and 1441 may be respectively stacked on the second layers 1413, 1423, 1433, and 1443.

Thicknesses of the first layers 1411, 1421, 1431, and 1441 and second layers 1413, 1423, 1433, and 1443 may be less than or equal to a critical thickness for pseudomorphic growth. The critical thickness for pseudomorphic growth may differ according to materials of the first layers 1411, 1421, 1431, and 1441 and second layers 1413, 1423, 1433, and 1443. For example, when the first layers 1411, 1421, 1431, and 1441 include Alx1Iny1Ga1-x1-y1N and the second layers 1413, 1423, 1433, and 1443 include Alx2Iny2Ga1-x2-y2N (0<x1≦1, 0≦x2<1, 0≦y1<1, 0≦y2<1, and x1>x2), the thicknesses of the first layers 1411, 1421, 1431, and 1441 and second layers 1413, 1423, 1433, and 1443 may be about several Å to about several nm to be less than or equal to the critical thickness for pseudomorphic growth.

At least one of the plurality of nitride semiconductor layers 1411 through 1443 may have a different thickness according to a location of the layer within the stack. When a thickness of a layer is different according to a location within the stack, a thickness ratio with an adjacent layer varies. When the thickness ratio with the adjacent layer varies, an average lattice constant with the adjacent layer also varies. As such, a stress effect in the superlattice layer 130 may be generated by using the average lattice constant.

For example, as shown in FIG. 2A, the first layers 1411, 1421, 1431, and 1441 and the second layers 1413, 1423, 1433, and 1443 may have different thicknesses according to their locations within the stack. When the first layers 1411, 1421, 1431, and 1441 and the second layers 1413, 1423, 1433, and 1443 have different thicknesses, the thickness ratios of first layers 1411, 1421, 1431, and 1441 and the second layers 1413, 1423, 1433, and 1443 forming the complex layers 141 through 144 may be different according to the complex layers 141 through 144. For example, when the thickness of the first layer 1441 of the complex layer 144 disposed on top is 1 nm and the thickness of the second layer 1443 is 5 nm, and the thickness of the first layer 1431 of the complex layer 143 disposed below the complex layer 144 is 2 nm and the thickness of the second layer 1433 is 4 nm, a thickness ratio of the first and second layers 1441 and 1443 of the complex layer 144 disposed on top is 1:5, and a thickness ratio of the first and second layers 1431 and 1433 of the complex layer 143 disposed below the complex layer 144 is 2:4. A lattice constant difference is generated between the complex layers 143 and 144 based on a thickness ratio difference between the complex layers 143 and 144, and a stress effect may be generated between the complex layers 143 and 144 by using the lattice constant difference.

When at least one of the first layers 1411, 1421, 1431, and 1441 and second layers 1413, 1423, 1433, and 1443 have different thicknesses according to the stacked locations, all of the first layers 1411, 1421, 1431, and 1441 and the second layers 1413, 1423, 1433, and 1443 may have different thicknesses according to the stacked locations. Alternatively, only the first layers 1411, 1421, 1431, and 1441 or only the second layers 1413, 1423, 1433, and 1443 may have different thicknesses according to their locations within the stack.

When all of the first layers 1411, 1421, 1431, and 1441 and the second layers 1413, 1423, 1433, and 1443 have different thicknesses based on their locations within the stack, the thicknesses of the first layers 1411, 1421, 1431, and 1441 and the second layers 1413, 1423, 1433, and 1443 may increase or decrease from the nitride nucleation layer 120 of FIG. 1 toward the gallium nitride-based semiconductor layer 160 of FIG. 1. In other words, a thickness change of the first layers 1411, 1421, 1431, and 1441 and the second layers 1413, 1423, 1433, and 1443 may have a stepped or continuous grade.

For example, as shown in FIG. 2A, the thicknesses of the first layers 1411, 1421, 1431, and 1441 may decrease toward the gallium nitride-based semiconductor layer 160. Further, the thicknesses of the second layers 1413, 1423, 1433, and 1443 may increase toward the gallium nitride-based semiconductor layer 160. In other words, the thickness of the first layer 1411 contacting the nitride nucleation layer 120 from among the first layers 1411, 1421, 1431, and 1441 that are spaced apart from each other is thickest, and the thickness of the first layer 1441 disposed closest to the gallium nitride-based semiconductor layer 160 is thinnest. As such, the thicknesses of the first layers 1421 and 1431 decrease toward the gallium nitride-based semiconductor layer 160. On the other hand, the thickness of the second layer 1413 disposed closest to the nitride nucleation layer 120 from among the second layers 1413, 1423, 1433, and 1443 that are spaced apart from each other is thinnest, and the thickness of the second layer 1443 disposed closest to the gallium nitride-based semiconductor layer 160 is thickest as the thicknesses of the second layers 1423 and 1433 increase toward the gallium nitride-based semiconductor layer 160. As the thicknesses increase or decrease, the first layer 1411 directly contacting the nitride nucleation layer 120 and the second layer 1443 contacting the gallium nitride-based semiconductor layer 160 may be the thickest. In this case, because the first layer 1411 and the second layer 1443 that are the thickest are closest to intrinsic lattice constants compared to the first layers 1421, 1431, and 1441 and the second layers 1413, 1423, and 1433, the first layer 1411 and the second layer 1443 may apply a larger stress to the gallium nitride-based semiconductor layer 160 and the nitride nucleation layer 120.

Alternatively, as shown in FIG. 2B, the thicknesses of the first layers 1411, 1421, 1431, and 1441 may increase toward the gallium nitride-based semiconductor layer 160, and the thicknesses of the second layers 1413, 1423, 1433, and 1443 may decrease toward the gallium nitride-based semiconductor layer 160.

Alternatively, when the first layers 1411, 1421, 1431, and 1441 and the second layers 1413, 1423, 1433, and 1443 have different thicknesses, the thickness changes according to the stacked locations may not have a uniform directivity, i.e., the thicknesses may be random as shown in FIG. 3. Here, a random thickness change has irregular directivity and may be realized via a desired (or alternatively, predetermined) table of random numbers.

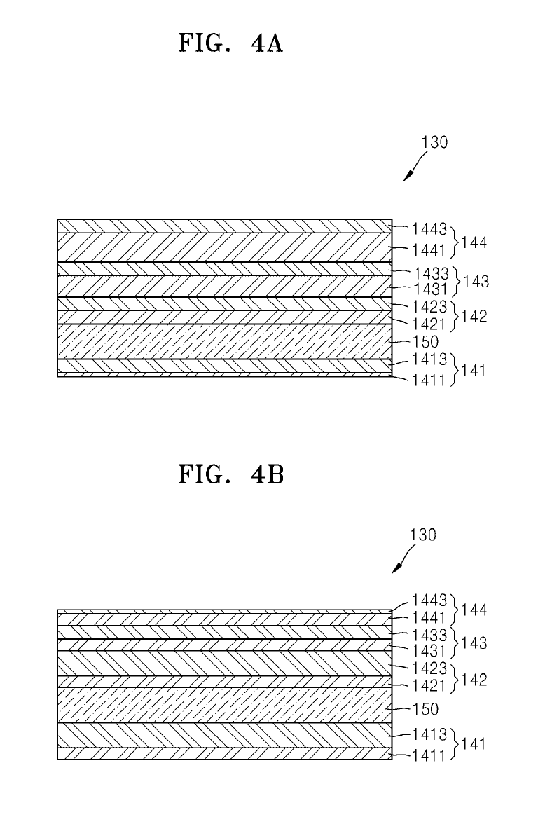

Alternatively, as described above, some of the nitride semiconductor layers 1411 through 1443, for example, only the first layers 1411, 1421, 1431, and 1441 or only the second layers 1413, 1423, 1433, and 1443 may have different thicknesses. As shown in FIG. 4A, the second layers 1413, 1423, 1433, and 1443 have uniform thicknesses, whereas the first layers 1411, 1421, 1431, and 1441 have different thicknesses based on their locations in the stack. On the other hand, as shown in FIG. 4B, the first layers 1411, 1421, 1431, and 1441 have uniform thicknesses, whereas the second layers 1413, 1423, 1433, and 1443 have different thicknesses based on their locations in the stack. The thicknesses of the first layers 1411, 1421, 1431, and 1441 or the second layers 1413, 1423, 1433, and 1443 may increase or decrease toward the gallium nitride-based semiconductor layer 160 as shown in FIG. 4A or 4B, but alternatively, may be randomly changed as shown in FIG. 3.

Referring back to FIG. 2A, the superlattice layer 130 may further include a stress control layer 150. By including the stress control layer 150, compressive stress is provided to the nitride semiconductor layers 1413 and 1421 adjacent to the stress control layer 150 inside of the superlattice layer 130, such that the entire superlattice layer 130 increases the compressive stress applied to the gallium nitride-based semiconductor layer 160. As such, it may be said that the superlattice layer 130 is configured to apply compressive stress on the gallium nitride-based semiconductor layer to compensate for tensile stress generated by thermal expansion of the gallium nitride-based semiconductor layer.

The stress control layer 150 may have a thickness exceeding the critical thickness for pseudomorphic growth. Accordingly, the stress control layer 150 may have a material that hast an intrinsic lattice constant. The stress control layer 150 may include Alₓ₃In_{y3}Ga_{1-x3-y3}N (here, 0<x3≦1 and 0≦y3<1). For example, when the stress control layer 150 is formed of AlN, the stress control layer 150 may have a thickness exceeding the critical thickness for pseudomorphic growth by 3 nm.

The stress control layer 150 may have a thickness that does not exceed a crack strength of the material used for the control layer 150. As described above, the stress control layer 150 has the intrinsic lattice constant by exceeding the critical thickness for pseudomorphic growth and applies the compressive stress to the first layer 1421 disposed on top. At this time, the stress control layer 150 experiences tensile stress in reaction to the compressive stress. As a thickness t5 of the stress control layer 150 is increased, the tensile stress applied to the stress control layer 150 is increased. When the tensile stress applied to the stress control layer 150 is excessively increased, the stress control layer 150 may crack. Accordingly, the stress control layer 150 may have a thickness that withstands the tensile stress applied by the first layer 1421 disposed on top without cracking, i.e., a thickness that does not exceed the material crack strength. When the stress control layer 150 is formed of AlN, the thickness satisfying the material crack strength is less than or equal to about 20 nm. Accordingly, when the stress control layer 150 is formed of AlN, the thickness t5 of the stress control layer 150 may exceed about 3 nm and be less than or equal to about 20 nm so as to provide an optimum compressive stress to an adjacent layer and not crack.

When the stress control layer 150 is disposed inside the superlattice layer 130, the stress control layer 150 may be disposed between the complex layers 141 through 144, as shown in FIGS. 2A and 2B.

When the stress control layer 150 is disposed between the complex layers 141 through 144, the stress control layer 150 may contact the complex layer 141 disposed at the bottom and contact the complex layer 142 disposed at the top.

Here, thickness changes of the first layers 1411 and 1421 and second layers 1413 and 1423 of the complex layers 141 and 142 disposed at the bottom and top of the stress control layer 150 may have a grade. For example, a thickness t11 of the first layer 1411 of the complex layer 141 disposed at the bottom of the stress control layer 150 may be thicker than a thickness t21 of the first layer 1421 of the complex layer 142 disposed at the top of the stress control layer 150. Further, a thickness t13 of the second layer 1413 of the complex layer 141 disposed at the bottom of the stress control layer 150 may be thinner than a thickness t23 of the second layer 1423 of the complex layer 142 disposed at the top of the stress control layer 150. Alternatively, as shown in FIG. 2B, the thickness t11 of the first layer 1411 of the complex layer 141 disposed at the bottom of the stress control layer 150 may be thinner than the thickness t21 of the first layer 1421 of the complex layer 142 disposed at the top of the stress control layer 150. Still referring to FIG. 2B the thickness t13 of the second layer 1413 of the complex layer 141 disposed at the bottom of the stress control layer 150 may be thicker than the thickness t23 of the second layer 1423 of the complex layer 142 disposed at the top of the stress control layer 150.

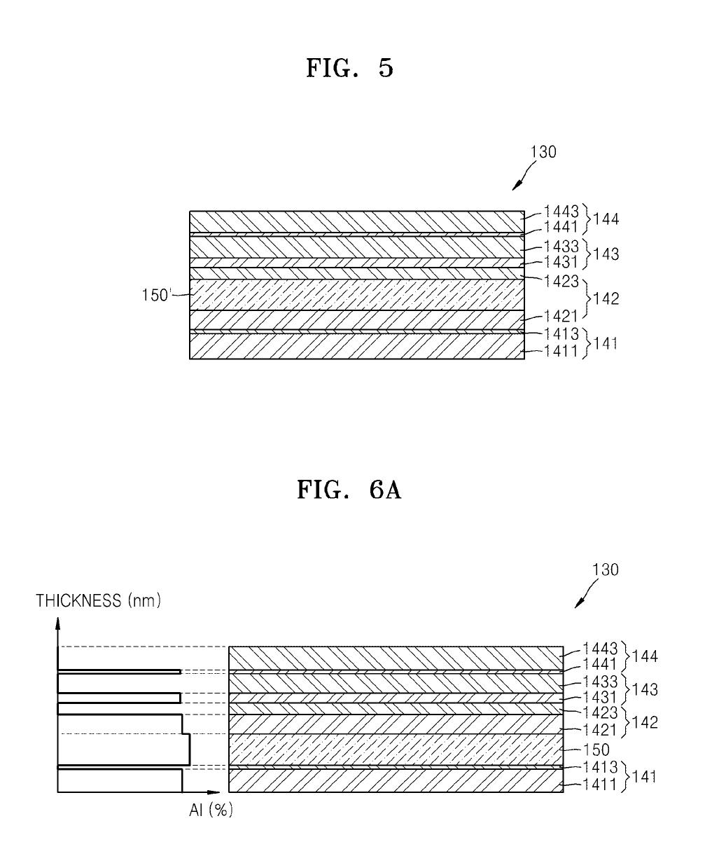

Alternatively, when the stress control layer 150 is disposed inside the superlattice layer 130, the stress control layer 150 may be disposed inside one of the complex layers 141 through 144, i.e., between the nitride semiconductor layers 1411 and 1413. For example, as shown in FIG. 5, a stress control layer 150′ may be disposed inside the complex layer 142, i.e., between the first and second layers 1421 and 1423 of the complex layer 142.

The stress control layer 150 is illustrated in above drawings as an individual layer from an adjacent nitride semiconductor layer, but alternatively, may be integrally formed with the adjacent nitride semiconductor layer. For example, in FIG. 2A, the stress control layer 150 and the first layer 1421 adjacent thereto may be integrally formed. Also, the number of stress control layers 150 described above is one. However, example embodiments are not limited thereto. Although not illustrated, a plurality of the stress control layers 150 may be respectively disposed between or inside the complex layers 141 through 144.

Compositions of the nitride semiconductor layers 1411 through 1443 forming the complex layers 141 through 144 and the stress control layer 150 may vary.

For example, compositions of the first layers 1411, 1421, 1431, and 1441, the second layers 1413, 1423, 1433, and 1443, and the stress control layer 150 may be fixed. For example, as shown in FIG. 6A, when the first layers 1411, 1421, 1431 and 1441 include Alₓ₁In_{y1}Ga_{1-x1-y1}N, the second layers 1413, 1423, 1433, and 1443 include Alₓ₂In_{y2}Ga_{1-x2-y2}N, and the stress control layer 150 includes Alₓ₃In_{y3}Ga_{1-x3-y3}N, values of x1, x2, x3, y1, y2, and y3 may be fixed. In FIG. 6A, an Al amount (x3) of the stress control layer 150 is higher than Al amounts (x1) of the first layers 1411, 1421, 1431, and 1441. However, when the stress control layer 150 and the first layer 1421 are integrally formed, the Al amounts may be the same.

Alternatively, at least one of the first layers 1411, 1421, 1431, and 1441, the second layers 1413, 1423, 1433, and 1443, and the stress control layer 150 may have a changing composition. As a composition changes, a critical thickness of a corresponding layer for pseudomorphic growth may change. Accordingly, a lattice constant realizable via a thickness change may vary, and thus, various kinds of stress are applicable.

When the composition changes in the thickness direction, at least any one of x1, x2, and x3 may change when the first layers 1411, 1421, 1431, and 1441 include Alₓ₁In_{y1}Ga_{1-x1-y1}N, the second layers 1413, 1423, 1433, and 1443 include Alₓ₂In_{y2}Ga_{1-x2-y2}N, and the stress control layer 150 includes Alₓ₃In_{y3}Ga_{1-x3-y3}N. For example, as shown in FIG. 6B, Al amounts (x1) of the first layers 1411, 1421, 1431, and 1441 may change within each of the first layers 1411, 1421, 1431, and 1441.

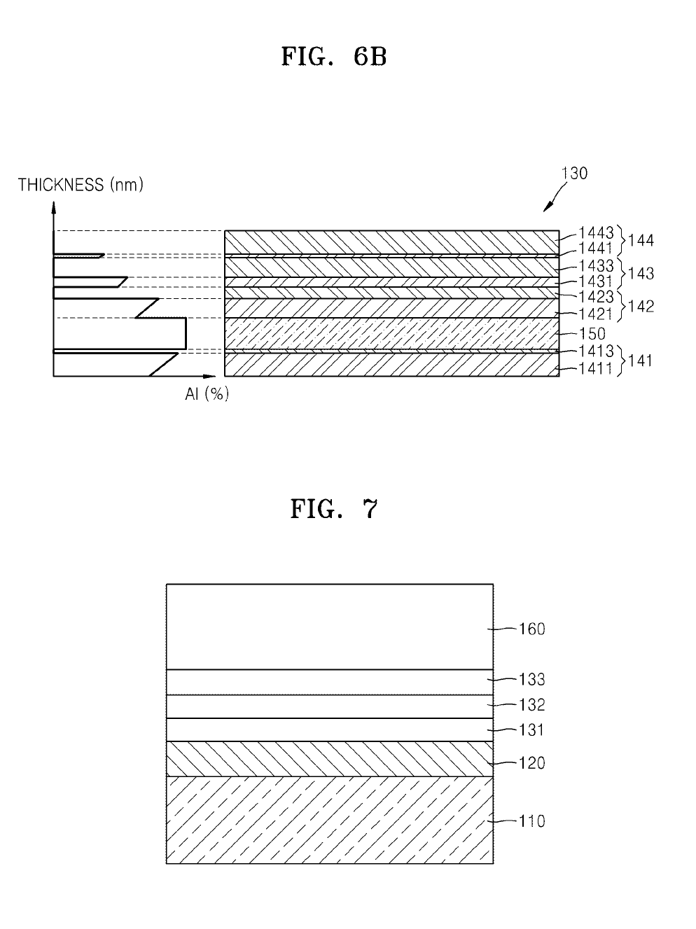

FIG. 7 is a view schematically illustrating first through third superlattice layers 131 through 133 according to an example embodiment. Referring to FIG. 7, the first superlattice layer 131 may be formed on the nitride nucleation layer 120, the second superlattice layer 132 may be formed on the first superlattice layer 131, and the third superlattice layer 133 may be formed on the second superlattice layer 132. Average Al compositions of the first through third superlattice layers 131 through 133 decrease from the nitride nucleation layer 120 toward the gallium nitride-based semiconductor layer 160. For example, the average Al composition of the first superlattice layer 131 may be 0.75, the average Al composition of the second superlattice layer 132 may be 0.5, and the average Al composition of the third superlattice layer 133 may be 0.25. As such, since the average Al composition of the first superlattice layer 131 formed on the nitride nucleation layer 120 is the highest, a lattice constant of the first superlattice layer 131 may be closest to that of the nitride nucleation layer 120, and since the average Al composition of the third superlattice layer 133 adjacent to the gallium nitride-based semiconductor layer 160 is the lowest, a lattice constant of the third superlattice layer 133 may be closest to that of the gallium nitride-based semiconductor layer 160. Accordingly, by reducing a lattice constant difference with respect to the gallium nitride-based semiconductor layer 160, dislocation density generated due to a lattice constant difference may be reduced.

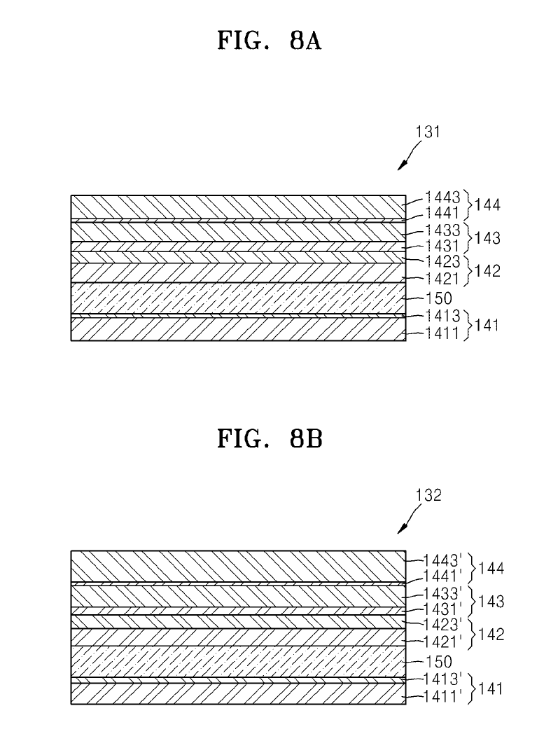

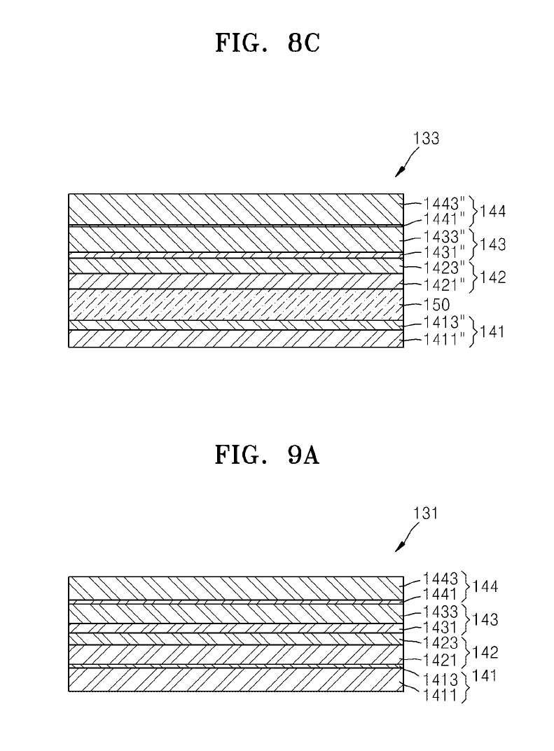

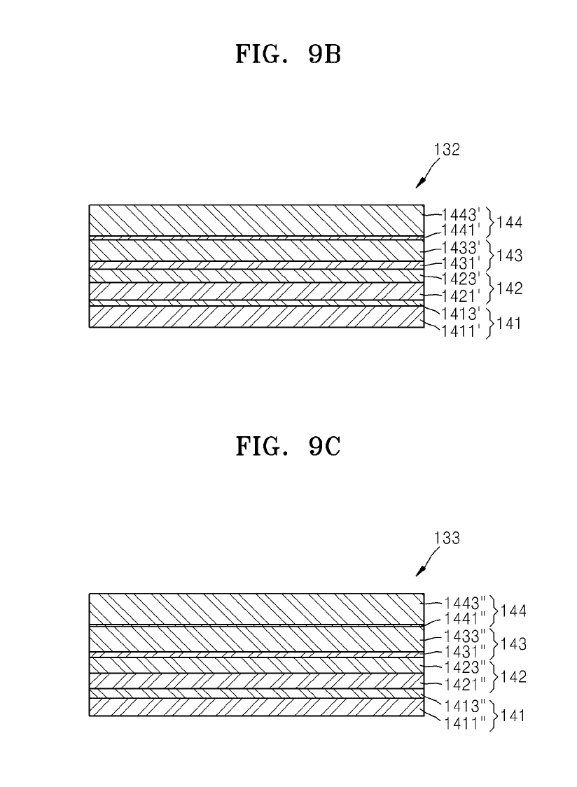

FIGS. 8A through 8C and 9A through 9C are magnified views illustrating the first through third of superlattice layers 131 through 133 of FIG. 7, according to at least one example embodiment.

Referring to FIGS. 8A through 8C, the first through third superlattice layers 131 through 133 each include the complex layers 141 through 144, 141′ through 144′, and 141″ through 144″ and the stress control layer 150 disposed between the complex layers 141 through 144, 141′ through 144′, and 141″ through 144″ wherein the complex layers 141 through 144 include first layers 1411 through 1441, 1411′ through 1441′, and 1411″ through 1441″ and second layers 1413 through 1443, 1413′ through 1443′, and 1413″ through 1443″, which are a plurality of nitride semiconductor layers having different thicknesses based on their locations within the superlattice layers. In order to change the average Al compositions of the first through third superlattice layers 131 through 133, a composition and thickness of each layer may be considered. For example, when first layers 1411 through 1441, 1411′ through 1441′, and 1411″ through 1441″ include AlGaN, the second layers 1413 through 1443, 1413′ through 1443′, and 1413″ through 1443″ include GaN, and the stress control layer 150 includes AlN, a thickness ratio of the first layers 1411 through 1441 having the highest Al compositions by including a plurality of layers, occupying the first through third superlattice layers 131 through 133, may operate as an important factor. Accordingly, the thickness ratio of the first layers 1411 through 1441 in the entire thickness of the first superlattice layer 131 contacting the nitride nucleation layer 120 (refer to FIG. 8A) may be higher than the thickness ratio of the first layers 1411′ through 1441′ in the entire thickness of the second superlattice layer 132 disposed on the first superlattice layer 131 (refer to FIG. 8B). Also, the thickness ratio of the first layers 1411″ through 1441″ in the entire thickness of the third superlattice layer 133 adjacent to the gallium nitride-based semiconductor layer 160 (refer to FIG. 8C) may be lower than the thickness ratio of the first layer 1411′ through 1441′ in the entire thickness of the second superlattice layer 132 disposed below the third superlattice layer 133 (refer to FIG. 8B). As such, the thickness ratios occupied by the first layers 1411 through 1441, 1411′ through 1441′, and 1411″ through 1441″ in the first through third superlattice layers 131 through 133 may decrease toward the gallium nitride-based semiconductor layer 160. Accordingly, the average Al compositions of the first through third superlattice layers 131 through 133 sequentially decrease, and thus, the lattice constant difference between the gallium nitride-based semiconductor layer 160 and the third superlattice layer 133 adjacent thereto may be reduced. In other words, the average Al composition of the second superlattice layer 132 may be lower than that of the first superlattice layer 131 and higher than that of the third superlattice layer 133, and thus, the lattice constant difference between the gallium nitride-based semiconductor layer 160 and the third superlattice layer 133 adjacent thereto may be reduced.

In each of the first through third superlattice layers 131 through 133 of FIGS. 9A through 9C, the complex layers 141 through 144, 141′ through 144′, and 141″ through 144″ including the first layers 1411 through 1441, 1411′ through 1441′, and 1411″ through 1441″ and second layers 1413 through 1443, 1413′ through 1443′, and 1413″ through 1443″, which are nitride semiconductor layers having different thicknesses according to the stacked locations, are repeatedly stacked on each other. This is similar to at least one of the above example embodiments, except that the first through third superlattice layers 131 through 133 do not include the stress control layer 150.

In order to change the average Al composition of the first through third superlattice layers 131 through 133, a composition and thickness of each layer may be considered. For example, when the first layers 1411 through 1441, 1411′ through 1441′, and 1411″ through 1441″ include AlN and the second layers 1413 through 1443, 1413′ through 1443′, and 1413″ through 1443″ include GaN, the thickness ratio of the first layers 1411 through 1441, 1411′ through 1441′, and 1411″ through 1441″ including Al, occupying the first through third superlattice layers 131 through 133, may operate as an important factor like FIG. 8. Accordingly, the thickness ratio of the first layers 1411 through 1441 in the entire thickness of the first superlattice layer 131 formed on the nitride nucleation layer 120 (refer to FIG. 9A) may be higher than the thickness ratio of the first layers 1411′ through 1441′ in the entire thickness of the second superlattice layer 132 disposed thereon (refer to FIG. 9B). Also, the thickness ratio of the first layers 1411″ through 1441″ in the entire thickness of the third superlattice layer 133 adjacent to the gallium nitride-based semiconductor layer 160 (refer to FIG. 9C) may be lower than the thickness ratio of the first layers 1411′ through 1441′ in the entire thickness of the second superlattice layer 132 disposed therebelow (refer to FIG. 9B). Accordingly, the average Al compositions of the first through third superlattice layers 131 through 133 may sequentially decrease, and thus, the lattice constant difference between the gallium nitride-based semiconductor layer 160 and the third superlattice layer 133 adjacent thereto may be reduced. In other words, the average Al composition of the second superlattice layer 132 may be lower than that of the first superlattice layer 131 and higher than that of the third superlattice layer 133, and thus, the lattice constant difference between the gallium nitride-based semiconductor layer 160 and the third superlattice layer 133 adjacent thereto may be reduced.

The gallium nitride-based semiconductor layer 160 is disposed on the superlattice layer 130 and the first through third superlattice layers 131 through 133 described above. The gallium nitride-based semiconductor layer 160 is a semiconductor layer based on gallium nitride, and includes gallium nitride (GaN), aluminum gallium nitride (AlGaN), indium gallium nitride (InGaN), aluminum indium gallium nitride (AlInGaN), or an alloy of gallium nitride.

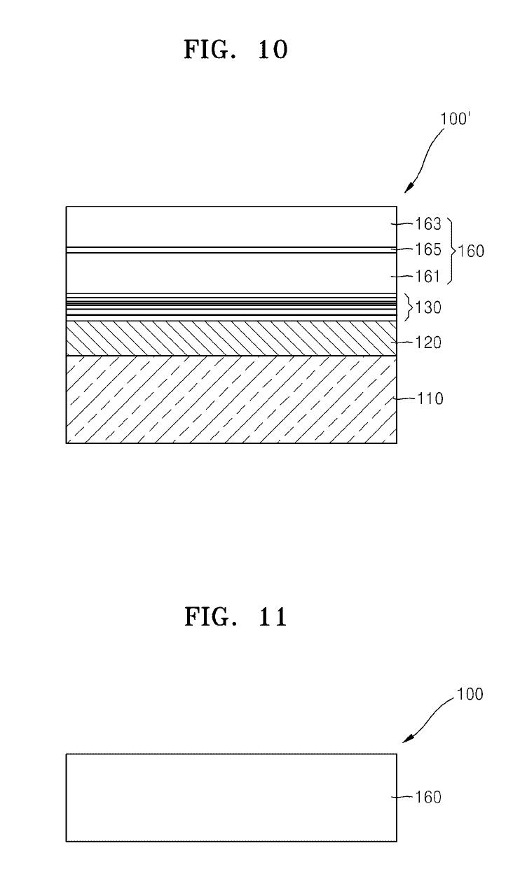

FIG. 10 is a view illustrating the semiconductor device 100′ applied to a light-emitting diode, according to another example embodiment. The semiconductor device 100′ of FIG. 10 may include the silicon substrate 110, the nitride nucleation layer 120 disposed on the silicon substrate 110, the superlattice layer 130 disposed on the nitride nucleation layer 120, and at least one gallium nitride-based semiconductor layer 160 disposed on the superlattice layer 130. For example, a first gallium nitride-based semiconductor layer 161 and a second gallium nitride-based semiconductor layer 163 may be included as the at least one gallium nitride-based semiconductor layer 160 disposed on the superlattice layer 130. Also, an active layer 165 may be disposed between the first and second gallium nitride-based semiconductor layer 161 and 163. The first gallium nitride-based semiconductor layer 161 may be doped with a first type dopant, for example, n-type dopant. The second gallium nitride-based semiconductor layer 163 may be doped with a second type dopant, for example, a p-type dopant. As holes and electrons combine in the active layer 165, an amount of energy corresponding to an energy band gap of the active layer 165 may be emitted as light. The active layer 165 may include a multiple quantum well layer. The first and second gallium nitride-based semiconductor layers 161 and 163 may each have a single layer or a multi-layer structure, wherein each nitride semiconductor layer may be selectively doped or undoped.

A method of manufacturing the semiconductor device 100, according to an example embodiment will now be described with reference to FIGS. 1, 7, and 10.

The nitride nucleation layer 120, the superlattice layer 130, and the gallium nitride-based semiconductor layer 160 are stacked on the silicon substrate 110. The silicon substrate 110 includes Si and may have a large diameter. For example, the silicon substrate 110 may have a diameter equal to or above 8 inches.

The nitride nucleation layer 120 prevents a melt-back phenomenon generated as the silicon substrate 110 and the superlattice layer 130 or the silicon substrate 110 and the gallium nitride-based semiconductor layer 160 react with each other. Also, the nitride nucleation layer 120 may enable the superlattice layer 130 or the gallium nitride-based semiconductor layer 160, which is to be grown on the nitride nucleation layer 120, to be satisfactorily wetted. Such a nitride nucleation layer 120 may be formed of AlN.

The superlattice layers 130, 131, 132, and 133 described with reference to FIGS. 2 through 6 and 8 through 9 may be employed as the superlattice layer 130, and thus details thereof are not repeated here.

The gallium nitride-based semiconductor layer 160 is a semiconductor layer based on gallium nitride, and may include gallium nitride (GaN), aluminum gallium nitride (AlGaN), indium gallium nitride (InGaN), aluminum indium gallium nitride (AlInGaN), or an alloy of GaN.

As shown in FIG. 11, the silicon substrate 110, the nitride nucleation layer 120, and the superlattice layers 130, 131, 132, and 133 may be removed. In order to support the silicon substrate 110, the nitride nucleation layer 120, and the superlattice layers 130, 131, 132, and 133, a support substrate (not shown) may be further stacked on the gallium nitride-based semiconductor layer 160. The silicon substrate 110, the nitride nucleation layer 120, and the superlattice layers 130, 131, 132, and 133 may be removed while the gallium nitride-based semiconductor layer 160 is supported by the support substrate.

The semiconductor device 100 according to an example embodiment may grow the gallium nitride-based semiconductor layer 160 to a desired thickness by decreasing the tensile stress while growing the gallium nitride-based semiconductor layer 160 on the silicon substrate 110. Also, it is possible to manufacture a wafer having a large diameter by using the silicon substrate 110. The semiconductor device 100 according to an example embodiment may be applied not only to a light-emitting diode, but also to a Schottky diode, a laser diode, a field effect transistor, or a power device.

As described above, according to a semiconductor device of one or more example embodiments, cracks may be suppressed from being generated while forming a gallium nitride-based semiconductor layer by applying compressive stress on the gallium nitride-based semiconductor layer through a superlattice layer to compensate for tensile stress generated due to a thermal expansion coefficient difference. Accordingly, a growth thickness of the gallium nitride-based semiconductor layer may be increased.

It should be understood that the exemplary example embodiments described therein should be considered in a descriptive sense only and not for purposes of limitation. Descriptions of features or aspects within each example embodiment should typically be considered as available for other similar features or aspects in other example embodiments.

What is claimed is:

1. A semiconductor device comprising:
a silicon substrate;
a nitride nucleation layer disposed on the silicon substrate;
at least one superlattice layer disposed on the nitride nucleation layer; and
at least one gallium nitride-based semiconductor layer disposed on the superlattice layer, the at least one superlattice layer including,
a stack of complex layers, each complex layer including a first layer and a second layer such that each of the complex layers has a plurality of nitride semiconductor layers having different compositions, at least one of the plurality of nitride semiconductor layers having a different thickness based on a location of the at least one nitride semiconductor layer within the stack, and
at least one stress control layer having a thickness greater than a critical thickness for pseudomorphic growth, the at least one stress control layer being disposed between one of the plurality of nitride semiconductor layers and the complex layers.

2. The semiconductor device of claim 1, wherein the nitride nucleation layer comprises aluminum nitride (AlN).

3. The semiconductor device of claim 1, wherein each of the first layers comprises Alₓ₁In_{y1}Ga_{1-x1-y1}N and each of the second layers comprises Alₓ₂In_{y2}Ga_{1-x2-y2}N, and the first and second layers are stacked on each other, wherein 0<x1≦1, 0≦x2<1, x1>x2, 0≦y1<1, and 0≦y2<1.

4. The semiconductor device of claim 3, wherein the at least one stress control layer comprises Alₓ₃In_{y3}Ga_{1-x3-y3}N, wherein 0<x3≦1 and 0≦y3<1.

5. The semiconductor device of claim 1, wherein the at least one stress control layer has a thickness greater than 3 nm and less than or equal to 20 nm, so as not to exceed a crack strength.

6. The semiconductor device of claim 4, wherein at least one of the first layers and second layers within each of the complex layers has a different thickness based on a location of the first layers and second layers within the stack, and the thicknesses of at least one of the first layers and second layers increase or decrease from the nitride nucleation layer toward the at least one gallium nitride-based semiconductor layer.

7. The semiconductor device of claim 4, wherein at least one of the first layers and second layers within each complex layer has a different thickness that varies randomly within the stack.

8. The semiconductor device of claim 4, wherein the at least one stress control layer is between the first layer and the second layer.

9. The semiconductor device of claim 4, wherein the at least one stress control layer is integrally formed with the first layer.

10. The semiconductor device of claim 4, wherein each of the first layer and the second layer has a thickness of about several Å to about several nm, and the at least one stress control layer has a thickness of about several nm to about dozens of nm.

11. The semiconductor device of claim 4, wherein at least one value of x1, x2, and x3 changes according to at least one of a thickness of the first layer, second layer, and the at least one stress control layer.

12. The semiconductor device of claim 4, wherein the at least one superlattice layer is a plurality of superlattice layers and an average aluminum (Al) composition of each of the plurality of superlattice layers decreases from the nitride nucleation layer toward the at least one gallium nitride-based semiconductor layer.

13. A semiconductor device comprising:
a silicon substrate;
a nitride nucleation layer disposed on the silicon substrate;
a plurality of superlattice layers disposed on the nitride nucleation layer; and
at least one gallium nitride-based semiconductor layer formed on the plurality of superlattice layers,
wherein each of the plurality of superlattice layers including,
a stack of complex layers, each complex layer including a first layer and a second layer such that each of the complex layers has a plurality of nitride semiconductor layers having different compositions, and at least one of the plurality of nitride semiconductor layers having a different thickness based on a location of the at least one nitride semiconductor layer within the stack, and
an average Al composition of each of the plurality of superlattice layers decreases from the nitride nucleation layer toward the at least one gallium nitride-based semiconductor layer.

14. The semiconductor device of claim 13, wherein the nitride nucleation layer comprises AlN.

15. The semiconductor device of claim 13, wherein the first layer comprises Alₓ₁In_{y1}Ga_{1-x1-y1}N and the second layer comprises Alₓ₂In_{y2}Ga_{1-x2-y2}N, and the first and second layers are stacked on each other, wherein 0<x1≦1, 0≦x2<1, x1>x2, 0≦y1<1, and 0≦y2<1.

16. The semiconductor device of claim 15, wherein at least one of the first layers and second layers within each of the complex layers has a different thickness based on a location of the first layers and second layers within the stack, and the thicknesses of at least one of the first layers and second layers increase or decrease from the nitride nucleation layer toward the at least one gallium nitride-based semiconductor layer.

17. The semiconductor device of claim 15, wherein at least one of the first layers and the second layers within each complex layer has a different thickness that varies randomly within the stack.

18. The semiconductor device of claim 15, wherein the first layer and the second layer have thicknesses of about several Å to about several nm.

19. The semiconductor device of claim 15, wherein at least one value of x1 and x2 changes according to at least one of a thickness of the first layer and the second layer.

20. A superlattice layer, comprising:
a stack of complex layers, each complex layer including,
a plurality of nitride semiconductor layers having different compositions, at least one of the plurality of nitride semiconductor layers having a different thickness based on a location of the at least one nitride semiconductor layer within the stack, and
at least one stress control layer having a thickness greater than a critical thickness for pseudomorphic growth and disposed between the plurality of nitride semiconductor layers or between the complex layers in the stack.

21. A method of manufacturing a semiconductor device, the method comprising:
stacking a nitride nucleation layer on a silicon substrate;
stacking at least one superlattice layer on the nitride nucleation layer; and
stacking at least one gallium nitride-based semiconductor layer on the at least one superlattice layer, the superlattice layer including,
a stack of complex layers, each complex layer including a first layer and a second layer such that each of the complex layers has a plurality of nitride semiconductor layers having different compositions, at least one of the plurality of nitride semiconductor layers having a different thickness based on a location of the at least one nitride semiconductor layer within the stack, and
at least one stress control layer having a thickness greater than a critical thickness for pseudomorphic growth, the at least one stress control layer being disposed between one of the plurality of nitride semiconductor layers and the complex layers.

22. The method of claim 21, wherein the at least one stress control layer has a thickness greater than 3 nm and less than or equal to 20 nm, so as not to exceed a crack strength.

23. The method of claim 21, further comprising removing the silicon substrate, the nitride nucleation layer, and the at least one superlattice layer from the gallium nitride-based semiconductor layer.

24. A method of manufacturing a semiconductor device, the method comprising:
stacking a nitride nucleation layer on a silicon substrate;
stacking a plurality of superlattice layers on the nitride nucleation layer; and
stacking at least one gallium nitride-based semiconductor layer on the plurality of superlattice layers, each of the plurality of superlattice layers including,
a stack of complex layers, each complex layer including a first layer and a second layer such that each of the complex layers has a plurality of nitride semiconductor layers having different compositions, and at least one of the plurality of nitride semiconductor layers having a different thickness based on a location of the at least one nitride semiconductor layer within the stack, and
an average Al composition of each of the plurality of superlattice layers decreases from the nitride nucleation layer toward the at least one gallium nitride-based semiconductor layer.

25. The method of claim 24, further comprising removing the silicon substrate, the nitride nucleation layer, and the plurality of superlattice layers from the gallium nitride-based semiconductor layer.
